(19) United States
(12) Patent Application Publication
(10) Pub. No.: US 2026/0229841 A1
(43) Pub. Date: Aug. 6, 2026

(54) PHASE SYNCHRONIZATION LASER DEVICE

(71) Applicant: Mitsubishi Electric Corporation, Tokyo (JP)

(72) Inventors: Eisuke HARAGUCHI, Tokyo (JP); Hitomi ONO, Tokyo (JP); Tomohiro AKIYAMA, Tokyo (JP)

(73) Assignee: Mitsubishi Electric Corporation, Tokyo (JP)

(21) Appl. No.: 19/636,434

(22) Filed: Apr. 1, 2026

Related U.S. Application Data
(63) Continuation of application No. PCT/JP2023/046296, filed on Dec. 25, 2023.

(51) Int. Cl. H01S 5/068; H01S 5/0687

(52) U.S. Cl. CPC H01S 5/06821; H01S 5/0687

(57) ABSTRACT

A phase synchronization laser device includes: an optical circulator to receive laser light and output return light; an optical splitter to split the laser light into reference and signal light beams; element circuits each including a phase compensator to perform phase control on the split beams of signal light, and output the beams of signal light; optical partial reflection mirrors to allow the reference light or the beams of signal light to enter as beams of incident light, reflect part of the beams of incident light and allow the rest to transmit; and a photoelectric converter to accept and photoelectrically convert the return light, each element circuit performs frequency conversion on an output of the photoelectric converter and detects a phase error of the electrical signal, and each phase compensator compensates for the detected phase error.

### CROSS REFERENCE TO RELATED APPLICATION

This application is a Continuation of PCT International Application No. PCT/JP2023/046296, filed on Dec. 25, 2023, which is hereby expressly incorporated by reference into the present application.

### TECHNICAL FIELD

The present disclosure relates to a phase synchronization laser device.

### BACKGROUND ART

As a method of implementing a high power laser system, a technique called Coherent Beam Combining (CBC) is well known. Coherent beam combining is a technique that uses a single piece of laser light as seed light for light amplification, splits the laser light into a plurality of beams of laser light (signal light), optically amplifies each piece of split laser light, and synthesizes each piece of optically amplified laser light (see, for example, Patent Literature 1). The high power laser device that uses CBC outputs a single beam with high power and high brightness by aligning the phases of respective optical paths, and combining a plurality of beams.

### CITATION LIST

### Patent Literature

Patent Literature 1: JP 2000-323774 A

### SUMMARY OF INVENTION

### Technical Problem

The high power laser system described in Patent Literature 1 has a problem that needs larger optical parts for multiplexing local oscillation light and a plurality of beams of signal light as the number of beams of signal light increases.

The present disclosure has been made to solve such a problem, and an object of the present disclosure is to provide a phase synchronization laser device that can be miniaturized even in a case where the number of signals increases.

### Solution to Problem

A phase synchronization laser device according to the embodiment of the present disclosure includes: an optical circulator to accept, from a first port, laser light emitted from a reference light source, supply the laser light to a feed light path, and output, from a second port, return light accepted from a return light path; an optical splitter to split the laser light accepted from the optical circulator via the feed light path into reference light and a plurality of beams of signal light; a plurality of element circuits each including a phase compensator to perform phase control on the plurality of beams of signal light split by the optical splitter, and output the plurality of beams of signal light subjected to the phase control; a plurality of optical partial reflection mirrors to allow the reference light or the plurality of beams of signal light subjected to the phase control to enter as beams of incident light, reflect part of the beams of incident light as beams of reflection light, and allow a rest of the beams of incident light to transmit; and a photoelectric converter to accept and photoelectrically convert the return light, and output a photoelectrically converted electrical signal, the return light being laser light obtained by the optical splitter by multiplexing the plurality of beams of reflection light, each element circuit performs frequency conversion on the electrical signal output by the photoelectric converter, and detects a phase error of the electrical signal having a frequency component corresponding to each element circuit, and each phase compensator compensates for the detected phase error.

### Advantageous Effects of Invention

The phase synchronization laser device according to the embodiment of the present disclosure can be miniaturized more than conventional devices even in a case where the number of signals increases.

### BRIEF DESCRIPTION OF DRAWINGS

FIG. 1 is a diagram illustrating a configuration example of a phase synchronization laser device according to Embodiment 1.

FIG. 2 is a diagram illustrating a configuration example of an element circuit of the phase synchronization laser device according to Embodiment 1.

FIG. 3A is a conceptual view of a spectrum of a received signal received by a photodiode. FIG. 3B is a conceptual view of a spectrum of a received signal divided by a ½ frequency divider. FIG. 3C is a conceptual view of a spectrum of a received signal band-limited by a band limiting filter.

FIG. 4 is a diagram illustrating a configuration example of an element circuit of a phase synchronization laser device according to Embodiment 2.

FIG. 5 is a diagram illustrating a configuration example of a phase synchronization laser device according to Embodiment 3.

FIG. 6 is a diagram illustrating a configuration example of an element circuit of the phase synchronization laser device according to Embodiment 3.

FIG. 7 is a diagram illustrating an example of an output beam pattern in a case where the number of subarrays is three.

FIG. 8 is a diagram illustrating a configuration example of a phase synchronization laser device according to Embodiment 4.

FIG. 9 is a diagram illustrating a configuration example of an element circuit for local emission light of the phase synchronization laser device according to Embodiment 4.

FIG. 10 is a diagram illustrating a configuration example of an element circuit for signal light of the phase synchronization laser device according to Embodiment 4.

FIG. 11A is a conceptual view of a spectrum of a received signal of a local oscillation light unit. FIG. 11B is a conceptual view of a spectrum of a received signal divided by a ½ frequency divider. FIG. 11C is a conceptual view of a spectrum of a light signal of a subarray #1. FIG. 11D is a conceptual view of the spectrum of the received signal of the subarray #1. FIG. 11E is a conceptual view of a spectrum of a received signal of the subarray #1 band-limited by the band limiting filter.

FIG. 12 is a diagram illustrating a configuration example of a phase synchronization laser device according to Embodiment 5.

### DESCRIPTION OF EMBODIMENTS

Various embodiments of the present disclosure will be described in detail below with reference to the accompanying drawings. Note that components assigned the same or similar reference numerals in the drawings will have the same or similar components or functions, and redundant description of these components will be omitted. Furthermore, a term “or” in the present disclosure is used to mean an inclusive or unless specified otherwise.

### Embodiment 1

### <Configuration>

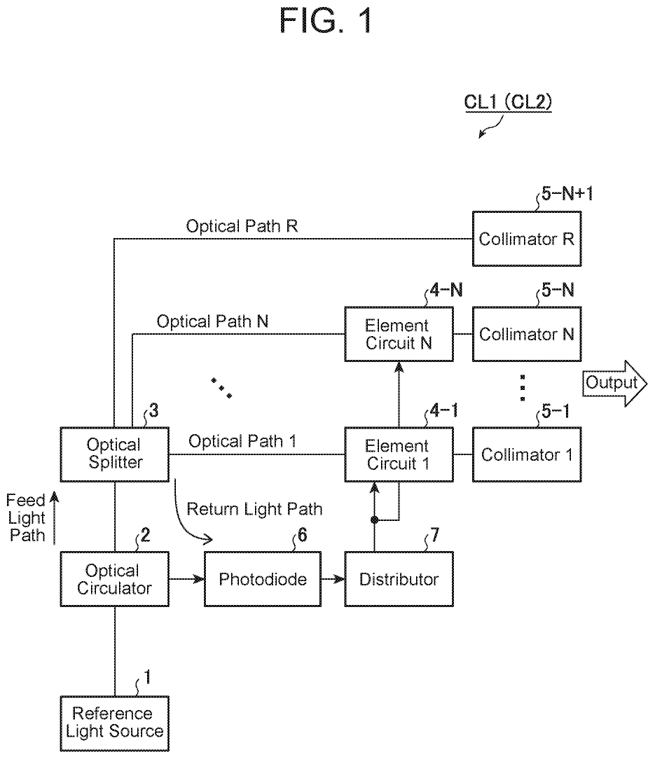

A phase synchronization laser device CL1 according to Embodiment 1 of the present disclosure will be described with reference to FIG. 1. As illustrated in FIG. 1, the phase synchronization laser device CL1 includes, for example, a reference light source 1, an optical circulator 2, an optical splitter 3, element circuits 4 (4-1 to 4-N), collimators 5 (5-1 to 5-N; optical partial reflection mirrors), a photodiode 6, and a distributor 7.

More specifically, the phase synchronization laser device CL1 includes the optical circulator 2 that accepts, from a first port, laser light emitted from the reference light source 1, supplies the laser light to a feed light path, and outputs, from a second port, return light accepted from a return light path, the optical splitter 3 that splits the laser light accepted from the optical circulator via the feed light path into reference light and a plurality of beams of signal light, the plurality of element circuits 4 that each include a phase compensator to perform phase control on the plurality of beams of signal light split by the optical splitter, and outputs the plurality of beams of signal light subjected to the phase control, the plurality of collimators 5 that allow the reference light or the plurality of beams of signal light subjected to the phase control to enter as beams of incident light, reflect part of the beams of incident light as beams of reflection light, and allow the rest of the beams of incident light to transmit, and the photodiode 6 that accepts and photoelectrically converts the return light, and outputs a photoelectrically converted electrical signal, and in which the return light is laser light obtained by the optical splitter by multiplexing the plurality of beams of reflection light, each element circuit performs frequency conversion on the electrical signal output by the photoelectric converter, and detects a phase error of the electrical signal having a frequency component corresponding to each element circuit, and each phase compensator compensates for the detected phase error. Hereinafter, components included in the phase synchronization laser device CL1 will be described in more detail.

### (Reference Light Source)

The reference light source 1 is, for example, a laser light source of a narrow line width that oscillates in a single mode. The reference light source 1 is connected with the optical circulator 2 via an optical fiber. The reference light source 1 supplies the oscillated laser light to the optical circulator 2 through the optical fiber.

### (Optical Circulator)

The optical circulator 2 is an optical circulator that includes three ports and separates optical paths for the feed light and the return light. For example, the optical circulator 2 accepts laser light as the feed light from the reference light source 1 through a port A (first port), and outputs the accepted feed light from a port B, and, on the other hand, outputs from a port C (second port) the return light accepted from the port B.

The optical circulator 2 is connected with the optical splitter 3 via the optical fiber. The optical circulator 2 supplies the feed light accepted from the reference light source 1 to the optical splitter 3 through the optical fiber.

Furthermore, the optical circulator 2 is connected with the photodiode 6 via the optical fiber. The optical circulator 2 supplies the return light accepted from the optical splitter 3 to the photodiode 6 through the optical fiber.

### (Optical Splitter; Optical Coupler)

The optical splitter 3 splits the feed light supplied from the optical circulator 2 into N beams of signal light and one piece of reference light. N represents an any positive integer. The optical splitter 3 is connected with the N element circuits 4 (4-1 to 4-N) via the optical fiber. Optical paths between the optical splitter 3 and the N element circuits 4 are indicated as an optical path 1, . . . , and an optical path N in FIG. 1. The optical splitter 3 supplies each piece of signal light to one element circuit 4 via one optical path. For example, the optical splitter 3 supplies certain signal light to the element circuit 4-1 via the optical path 1, and supplies another signal light to the element circuit 4-N via the optical path N.

Furthermore, the optical splitter 3 is connected with the collimator 5-N+1 (collimator R) via the optical fiber. An optical path between the optical splitter 3 and the collimator 5-N+1 (collimator R) is indicated as an optical path R in FIG. 1. The optical splitter 3 supplies the reference light (local oscillation light) to the collimator 5-N+1 (collimator R) via the optical path R.

Note that the optical splitter may be referred to as an optical coupler in the present disclosure. The optical splitter and the optical coupler are identical objects. A term, the optical coupler, and a term, the optical coupler, may be distinguished depending on a functional difference between use as a splitter for splitting a single piece of light into a plurality of beams of light and use as a coupler for coupling a plurality of beams as a single piece of light.

### (Element Circuit)

The element circuit 4 is a circuit that controls the optical phase of signal light. The element circuits 4-1 to 4-N employ the same configuration, and perform phase modulation (phase control) on beams of signal light input from the optical paths 1 to N to generate N phase modulated light signals (phase control light signals). The element circuits 4-1 to 4-N supply the generated phase modulation light signals to the collimators 5-1 to 5-N (a collimator 1 to a collimator 5-N). A more detailed configuration of the element circuit 4 will be described later.

### (Collimator)

The collimator 5 spatially outputs signal light to be accepted. When signal light is spatially output, return light is produced by Fresnel reflection. Note that the collimator is an example of an optical partial reflection mirror in the present disclosure.

### (Photodiode)

The photodiode 6 photoelectrically converts return light to be received, and supplies the photoelectrically converted electrical signal to the distributor 7. Note that the photodiode is an example of an photoelectric converter in the present disclosure.

### (Distributor)

The distributor 7 distributes a received signal that is an electrical signal received from the photodiode to the element circuits 4 (4-1 to 4-N).

### (Element Circuit; Details)

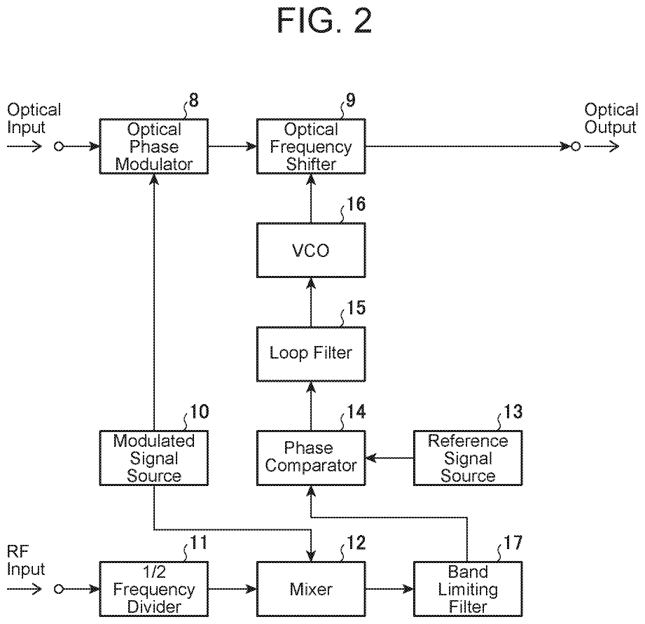

Next, a detailed configuration of the element circuit 4 will be described with reference to FIG. 2. As illustrated in FIG. 2, the element circuit 4 includes a modulated signal source 10, an optical phase modulator 8, an optical frequency shifter 9, a ½ frequency divider 11, a mixer 12, a band limiting filter 17, a reference signal source 13, a phase comparator 14, a loop filter 15, and a VCO 16.

### (Modulated Signal Source)

The modulated signal source 10 is a signal source that outputs a modulated signal (dithering signal) that is used to identify each piece of signal light and whose frequency differs per element.

### (Optical Phase Modulator)

The optical phase modulator 8 is driven by a modulated signal output from the modulated signal source 10 to modulate the phase of signal light. Mutually different modulated signals are supplied to the N element circuits 4 (4-1 to 4-N), and mutually different modulated signals are superimposed on the phases of the N beams of signal light.

### (Optical Frequency Shifter; Phase Compensator)

The optical frequency shifter 9 compensates for the phase of a light signal output from the optical phase modulator 8.

The optical frequency shifter 9 compensates for the phase of the light signal output from the optical phase modulator 8 by shifting by an amount corresponding to the frequency of the frequency-modulated signal output from the VCO 16. Since the phase is expressed as the time integration of the frequency, in other words, the frequency is expressed as time derivative of the phase, it is possible to perform phase control (phase compensation) by frequency control. The optical frequency shifter 9 outputs a phase-compensated light signal. Note that the optical frequency shifter 9 is an example of a phase compensator in the present disclosure.

### (½ Frequency Divider)

The ½ frequency divider 11 divides the frequency of a received signal, which is received by the photodiode 6 and distributed by the distributor 7, by a factor of ½, and outputs the divided signal. By this frequency division, the phase component corresponding to the return path of the return light is removed.

### (Mixer)

The mixer 12 mixes a signal output by the ½ frequency divider 11 and a modulated signal (dithering signal), and outputs the mixed signal.

### (Band Limiting Filter)

The band limiting filter 17 extracts a signal of a desired band among the signals output from the mixer 12.

### (Reference Signal Source)

The reference signal source 13 generates a reference signal that is a phase reference, and outputs the generated reference signal.

### (Phase Comparator)

The phase comparator 14 compares the phase of the reference signal accepted from the reference signal source 13 and the phase of the received signal accepted via the band limiting filter 17, and outputs a phase error signal that is a comparison result.

### (Loop Filter)

The loop filter 15 calculates a control signal from the phase error signal accepted from the phase comparator 14, and outputs the calculated control signal.

### (VCO; Voltage-Controlled Oscillator)

The VCO 16 oscillates the frequency-modulated signal at the frequency that follows the control signal to be output from the loop filter 15, and outputs the oscillated frequency-modulated signal.

### <Operation>

Next, an entire operation of the phase synchronization laser device CL1 will be described. Laser light output from the reference light source 1 is propagated by the optical circulator 2 to the feed light path. The laser light from the reference light source 1 propagates in the feed light path, and is split by the optical splitter 3 into laser light that is reference light (local oscillation light) for the optical path R and beams of laser light that are beams of signal light for the optical paths (signal light paths) 1 to N. After being split, the beams of signal light are spatially output from the collimators 5-1 to 5-N via the element circuits 4 (4-1 to 4-N), and the local oscillation light is spatially output from the collimator 5-N+1.

At a time of spatial output, return light (reflection light) is generated by Fresnel reflection. The return light of the signal light is input to the optical splitter 3 via the element circuit 4, and the return light (reflection light) of the local oscillation light is input to the optical splitter 3 as is, that is, without passing through the element circuit 4. The optical splitter 3 multiplexes (couples) a plurality of beams of return light of a plurality of beams of signal light, and the return light of the local oscillation light to generate multiplexed light. The multiplexed light output from the optical splitter 3 is propagated to the return light path by the optical circulator 2. Then, the multiplexed light is received by the photodiode 6, and is photoelectrically converted by the photodiode 6. Received signals that are electrical signals output from the photodiode 6 are distributed by the distributor 7 according to the number of beams of signal light and input to the element circuits 4.

Phase modulation is superimposed on the laser light input to the element circuit 4 by the optical phase modulator 8 driven by a weak modulated signal of the modulated signal source 10. The laser light output by the optical phase modulator 8 is subjected to frequency shift by the optical frequency shifter 9 to which a phase control signal is fed back, and the laser light subjected to frequency shift is output.

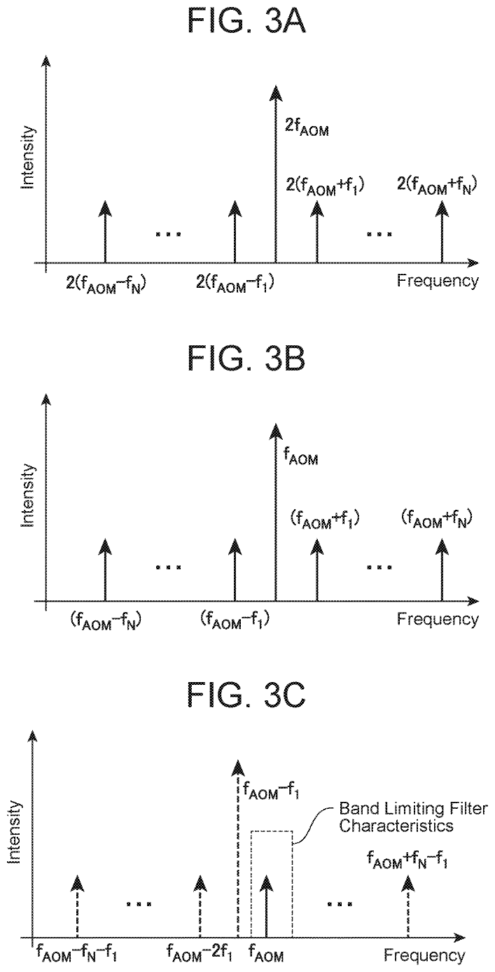

Here, FIG. 3A is a conceptual view of the spectrum of a received signal received by the photodiode 6. The laser light passes through the element circuit 4 twice as feed light and return light, and, if a frequency shift amount of the optical frequency shifter 9 is f_{AOM} and a modulation frequency of the modulated signal source 10 in an ith element circuit 4-i is fᵢ, a carrier signal has the frequency of 2f_{AOM} and a side carrier generated by phase modulation has the frequency of 2 (f_{AOM}±fᵢ). Here, by dividing the frequency using the ½ frequency divider 11, each frequency is halved as illustrated in FIG. 3B. Then, by performing frequency conversion using an output signal from the modulated signal source 10, the frequency of a signal (mixer output signal) output from the mixer 12 is f_{AOM}. After an unnecessary signal of the mixer output signal is suppressed by the band limiting filter 17 centered at the frequency f_{AOM}, a signal output from the band limiting filter 17 and the reference signal from the reference signal source 13 driven at the frequency (f_{AOM}) is subjected to phase comparison to extract an error signal with respect to the reference signal. FIG. 3C is a conceptual view of a spectrum of a received signal band-limited by the band limiting filter 17 in a case of i=1.

### (Establishment of Phase Synchronization)

A phase change amount of local oscillation light in one way along the optical path R is φ_{R}, a phase change amount of signal light in one way along an optical path i (i represents an integer from one to N) is φᵢ, and a phase control amount in the optical frequency shifter 9 in the element circuit 4 is φ_{AOM}. Beat signals of the signal received by the photodiode 6 in the optical path i and the optical path R are approximately expressed by the following equation.

$${I}_{i} = 2 \sqrt{{P}_{R} {P}_{i}} cos \{ 2 π \times 2 \times ( 〈 {f}_{AOM} + {f}_{i} ) t + {ϕ}_{R} - {ϕ}_{i} - {ϕ}_{AOM} ) \} \qquad ( 1 )$$

Focusing on a phase term of a Cos function, the signal phase after ½ division is φ_{R}−φᵢ−φ_{AOM}.

If the phase of the reference signal source 13 is φᵣ, a relationship of the following equation (2) holds at a time of establishment of phase synchronization.

$${ϕ}_{r} = {ϕ}_{R} - {ϕ}_{i} - {ϕ}_{AOM} \qquad ( 2 )$$

By deforming the equation (2), the following equation (3) can be obtained.

$${ϕ}_{AOM} = {ϕ}_{R} - {ϕ}_{i} - {ϕ}_{r} \qquad ( 3 )$$

Furthermore, the phase of signal light i to be spatially output is expressed by the following equation (4).

$$\begin{matrix}{ϕ}_{out - i} = {ϕ}_{i} + {ϕ}_{AOM} \\ = {ϕ}_{i} + {ϕ}_{R} - {ϕ}_{i} - {ϕ}_{r} \\ = {ϕ}_{R} - {ϕ}_{r}\end{matrix} \qquad ( 4 )$$

Accordingly, it is found that, in the phase synchronization laser device CL1 according to Embodiment 1, the signal light i to be spatially output does not depend on phase fluctuation (φᵢ) caused by the optical path i.

As described above, by establishing phase synchronization after dividing a received signal using Fresnel reflection in a collimator of signal light in a configuration where the signal light passes through a signal light path two times, it is possible to coherently synthesize a plurality of beams of light without the influence of phase fluctuation of the signal light path. This configuration can be configured only with a fiber system, so that an alignment or an optical system for phase error detection is unnecessary, and miniaturization is also possible when the number of signals increases. Furthermore, a configuration at a subsequent stage of the mixer of the element circuit is the same for all elements, and consequently is easy to adjust.

Although the above description has described the example where the optical frequency shifter 9 is used for phase synchronization, a configuration that uses a fiber stretcher or bias control of the optical phase modulator may be used instead of the optical frequency shifter 9.

### Embodiment 2

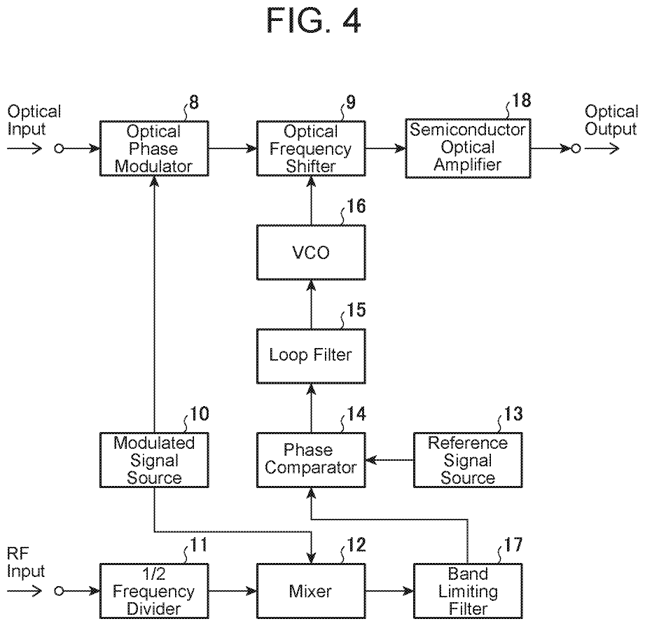

Hereinafter, a phase synchronization laser device CL2 according to Embodiment 2 will be described with reference FIG. 4. Note that an entire configuration of the phase synchronization laser device CL2 according to Embodiment 2 is the same as that of the phase synchronization laser device CL1 according to Embodiment 1, and therefore description thereof will not be repeated. FIG. 4 is a view illustrating a configuration of the element circuit of the phase synchronization laser device CL2 according to Embodiment 2, the same or similar elements as those of Embodiment 1 in FIG. 4 will be assigned the same reference numerals, and description thereof will not be repeated.

Embodiment 2 differs from Embodiment 1 in that, in Embodiment 2, a semiconductor optical amplifier 18 that does not include an isolator at an input/output end is added to an output of the optical frequency shifter 9. The semiconductor optical amplifier 18 is added, so that not only output light power is increased, but also a return light level is increased, and consequently it is possible to improve a signal-to-noise ratio (SNR), and achieve highly accurate optical phase synchronization.

A gain of the semiconductor optical amplifier 18 is assumed to be as G_{SOA}. In this case, the output light level is increased by G_{SOA} compared to Embodiment 1. Similarly, return light by Fresnel reflection is also increased by G_{SOA}. If the loss due to Fresnel reflection is IF, the return light level in Embodiment 1 is P_{AOM}−I_{F} in a case where an output light level of the optical frequency shifter is P_{AOM}. In a case where the configuration in FIG. 4 is used, a reception level is P_{AOM}+G_{SOA}−I_{F}+G_{SOA} and the reception level is increased by 2G_{SOA}.

As described above, by using the present embodiment, and by increasing not only the output light level, but also the return light level, it is possible to highly accurately establish optical phase synchronization. A reception level is weak in a phase error detection system that uses Fresnel reflection, and therefore there is a problem that accuracy of phase synchronization deteriorates compared to the conventional configuration. By using the present embodiment, it is possible to improve a reception SNR and perform highly accurate phase synchronization.

### Embodiment 3

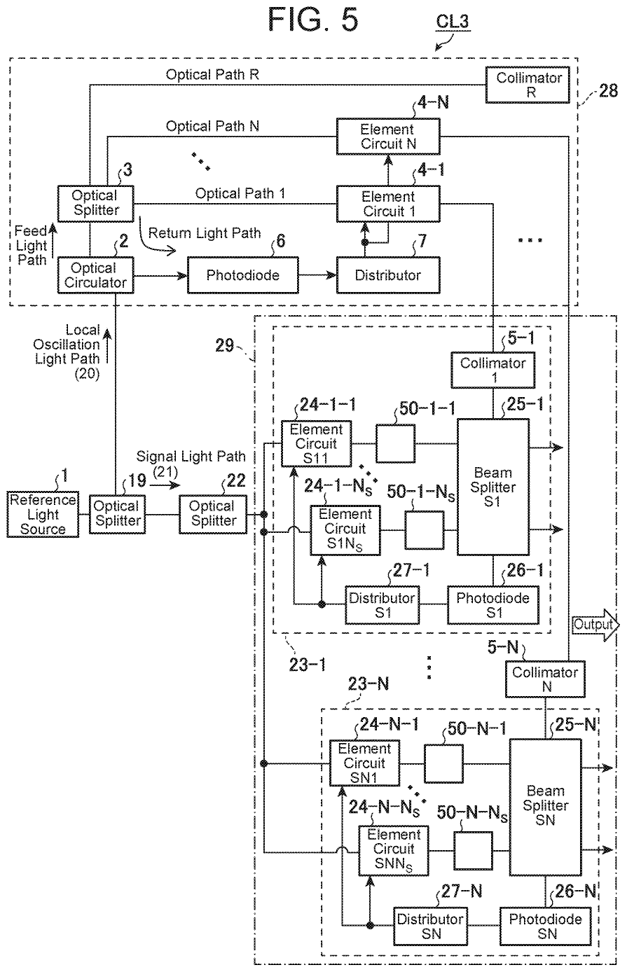

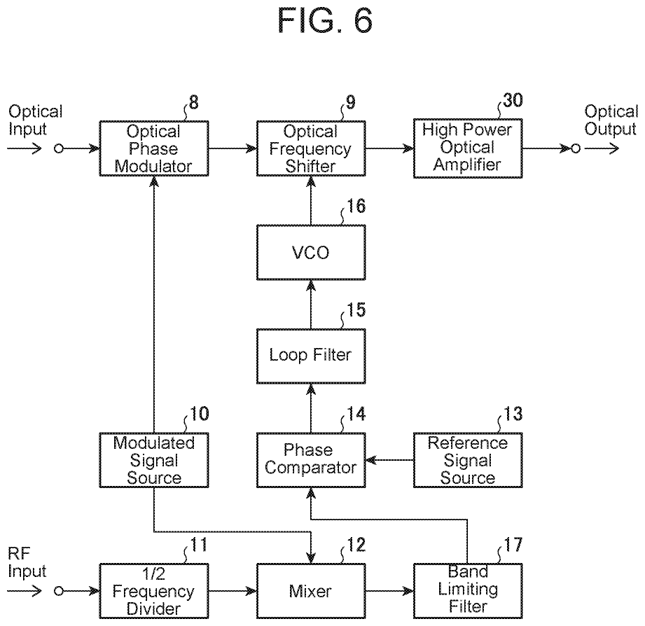

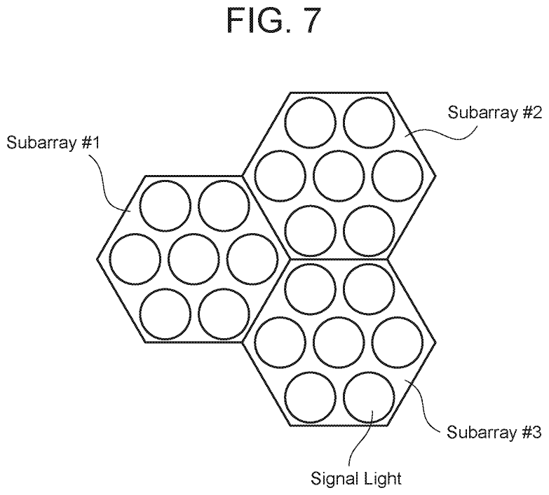

Hereinafter, a phase synchronization laser device CL3 according to Embodiment 3 will be described with reference FIGS. 5 to 7. FIG. 5 is a diagram illustrating an entire configuration example of the phase synchronization laser device CL3. FIG. 6 is a diagram illustrating a configuration example of an element circuit of the phase synchronization laser device CL3. FIG. 7 is a diagram illustrating an example of an output beam pattern in a case where the number of subarrays is three (N=3). The same or similar elements as those of Embodiment 1 in FIGS. 5 and 6 will be assigned the same reference numerals, and description thereof will not be repeated.

The phase synchronization laser device CL3 according to Embodiment 3 employs a configuration suitable for a case where a high power optical amplifier 30 which does not allow a reverse input such as a fiber amplifier or a waveguide type optical amplifier is used in a signal light path. More specifically, the phase synchronization laser device CL3 includes a local oscillation light control unit 28 that subarrays the configuration according to Embodiment 1 or Embodiment 2 and supplies a plurality of beams of local oscillation light, and by including this local oscillation light control unit 28, so that it is possible to subarray signal light.

The high power optical amplifier 30 such as a fiber amplifier that can obtain optical power having high power cannot receive a reverse input from an output side as described in Embodiment 2. Hence, the phase synchronization laser device CL3 including the high power optical amplifier 30 can subarray signal light as illustrated in FIG. 7 and increase the number of elements. In this regard, according to the configuration where phase synchronization of signal light is performed on a single piece of local oscillation light for subarraying, a beam diameter becomes larger when the number of elements increases and it is difficult to increase the signal light, and therefore it is conceivable to prepare a plurality of beams of local oscillation light having synchronized phases. Hence, in the present embodiment, the local oscillation light control unit 28 that does not include a high power optical amplifier performs phase synchronization that uses Fresnel reflection described in Embodiment 1 to prepare a plurality of beams of local oscillation light whose phases are synchronized. Consequently, it is possible to supply the plurality of beams of local oscillation light for which phase synchronization has been established, so that the phase synchronization laser device CL3 including the high power optical amplifier 30 can support an increase in the number of elements (an increase in the number of beams of signal light). That is, according to the configuration of the phase synchronization laser device CL3, it is possible to increase the number of subarrays in a scalable manner.

As illustrated in FIG. 5, the phase synchronization laser device CL3 according to Embodiment 3 includes the reference light source 1, an optical splitter 19 that splits laser light output from the reference light source 1 into laser light for a local oscillation optical path 20, and laser light for a signal light path 21, the local oscillation light control unit 28 that accepts the laser light from the local oscillation optical path 20 and generates a plurality of beams of local oscillation light for which phase synchronization has been established, an optical splitter 22 that splits the laser light from the signal light path 21 into a plurality of beams of signal light, and a signal light control unit 29 that accepts the plurality of beams of signal light split by the optical splitter 22 and controls the beams of signal light. The signal light control unit 29 includes a plurality of signal light subarrays obtained by subarraying the plurality of beams of signal light obtained from laser light emitted from the reference light source 1. The local oscillation light control unit 28 supplies the plurality of beams of local oscillation light subjected to phase synchronization with the plurality of signal light subarrays.

The local oscillation light control unit 28 employs the configuration described in accordance with Embodiment 1. In the example illustrated in FIG. 5, the local oscillation light control unit 28 generates N beams of local oscillation light for which phase synchronization has been established. N represents the number of subarrays.

More specifically, the local oscillation light control unit 28 includes the optical circulator 2 that accepts, from the first port, the laser light, supplies the laser light to the feed light path, and outputs, from the second port, the return light accepted from the return light path, the optical splitter 3 that splits the laser light accepted from the optical circulator 2 via the feed light path into reference light and the plurality of beams of local oscillation light, the plurality of element circuits 4 that each include the optical frequency shifter 9 (phase compensator) that performs phase control on the plurality of beams of local oscillation light split by the optical splitter, and outputs the plurality of beams of local oscillation light subjected to the phase control, the plurality of collimators 5 that allow the reference light or the plurality of beams of local oscillation light subjected to the phase control to enter as beams of incident light, reflect part of the beams of incident light as beams of reflection light, and allow the rest of the beams of incident light to transmit, and the photodiode 6 (first photoelectric converter) that accepts and photoelectrically converts the return light, and outputs a photoelectrically converted electrical signal, and in which the return light is laser light obtained by the optical splitter 3 by multiplexing the plurality of beams of reflection light, each element circuit 4 (first element circuit) performs frequency conversion on the electrical signal output by the photodiode 6, and detects a phase error of the electrical signal having a frequency component corresponding to each element circuit 4, and each optical frequency shifter 9 (phase compensator) compensates for this detected phase error. Note that, although the collimators 5-1 to 5-N are illustrated as components of the signal light control unit 29 in FIG. 5, the local oscillation light control unit 28 may include the collimators 5-1 to 5-N as described above.

As illustrated in FIG. 5, the signal light control unit 29 includes N signal light subarrays 23 (23-1 to 23-N). Each signal light subarray 23 includes element circuits 24 (24-N−1 to 24-N−N_{S}; second element circuits) the number of which corresponds to a number of beams of signal light N_{S} in the subarray, N_{S} collimators 50 (50-N−1 to 50-N−N_{S}) that correspond to the element circuits 24 (24-N−1 to 24-N−N_{S}) and collimate beams of signal light output from the element circuits, a beam splitter 25-N(SN) that accepts the beams of signal light output from the N_{S} collimators 50 (50-N−1 to 50-N−N_{S}) and the local oscillation light output from the collimator 5 (5-N), generates beams of multiplexed light, outputs part of generated beams of the multiplexed light as beams of signal light for output, and outputs part of generated beams of the multiplexed light as beams of signal light for phase error detection, a photodiode 26-N (second photoelectric converter) that photoelectrically converts the beams of signal light for phase error detection output from the beam splitter 25-N, and a distributor 27-N that distributes an electrical signal output from the photodiode 26-N to the plurality of element circuits 24.

Next, an entire operation of the phase synchronization laser device CL3 will be described. Laser light output from the reference light source 1 is split by an optical splitter 19 into laser light for the local oscillation optical path 20, and laser light for the signal light path 21.

In the local oscillation optical path 20, the local oscillation light control unit 28 implements phase synchronization using an output end of the collimator as a reference.

In the signal light path 21, the optical splitter 22 splits the laser light from the optical splitter 19 into a plurality (N×N_{S}) of beams of signal light. Note that, as described above, N_{S} represents the number of beams of signal light in a subarray, and N represents the number of subarrays. In a case where, for example, N_{S} is seven and N is three, the total number of elements is 21. Beams of local oscillation light the number of which corresponds to the number of subarrays is necessary, and the number of beams of local oscillation light is three. FIG. 7 illustrates an example of an output beam pattern in this case.

The beams of signal light split by the optical splitter 22 are collected every N_{S} beams as one signal light subarray 23. In each signal light subarray, the beams of signal light split by the optical splitter 22 are amplified by the element circuits 24 (24-N−1 to 24-N−N_{S}), and then are spatially output via the collimators (50-N−1 to 50-N−N_{S}). The spatially output beams of signal light (transmission light) are split into beams of signal light for phase error detection and beams of signal light for output by the beam splitter 25-N (SN). The beams of signal light for phase error detection are multiplexed (photomixed) with local oscillation light input from an opposite port of the beam splitter 25-N (SN), and mixed light generated by multiplexing (mixing) is received by the photodiode 26-N. A received signal is distributed to each element circuit by the distributor 27-N.

In the element circuits 24 (24-1−1 to 24-N−N_{S}), the signal light subjected to phase control by the optical frequency shifter 9 for phase control is amplified by the high power optical amplifier 30, and the amplified signal light is output.

The above-described phase synchronization laser device CL3 can perform optical phase synchronization between a plurality of beams of local oscillation light inline, so that it is possible to achieve scalability with the reduced number of alignments.

### Embodiment 4

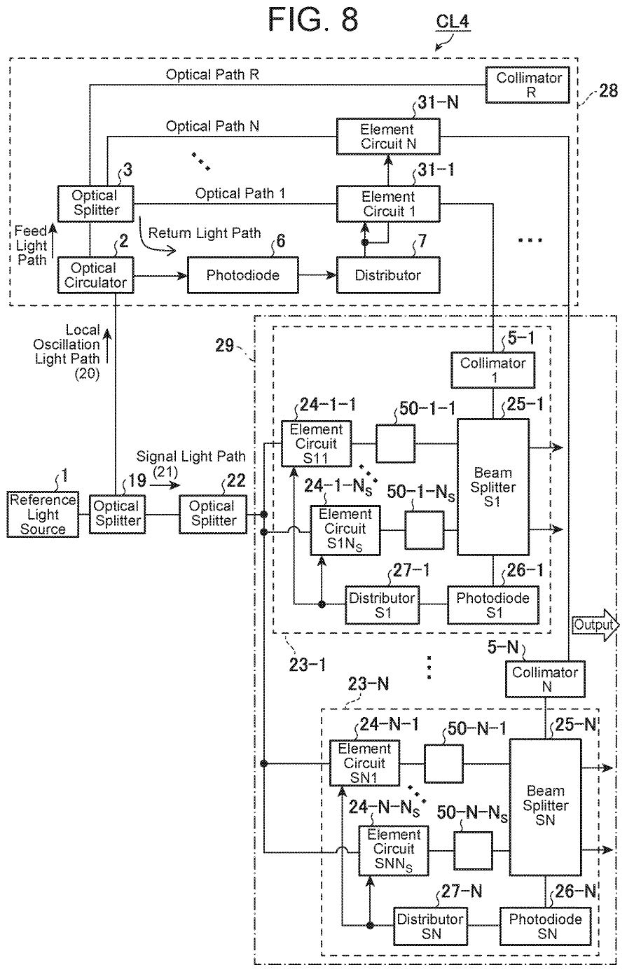

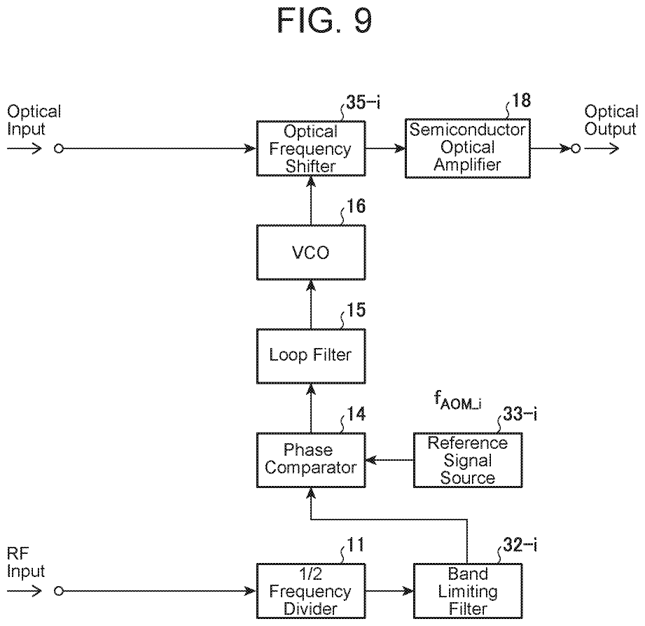

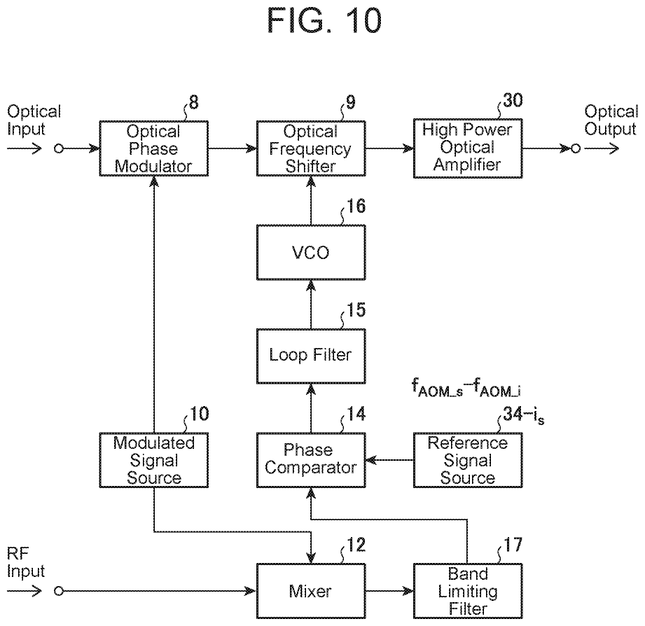

A phase synchronization laser device CL4 according to Embodiment 4 will be described with reference FIGS. 8 to 11. FIG. 8 is a diagram illustrating an entire configuration example of the phase synchronization laser device PL4. FIG. 9 is a diagram illustrating a configuration example of an element circuit for local oscillation light of the phase synchronization laser device CL4. FIG. 10 is a diagram illustrating a configuration example of an element circuit for signal light of the phase synchronization laser device CL4. The same or similar elements as those of Embodiment 1, Embodiment 2, or Embodiment 3 in FIGS. 8, 9, and 10 will be assigned the same reference numerals, and description thereof will not be repeated.

Embodiment 4 differs from Embodiment 3 in that all optical frequency shifters for local oscillation light have different frequencies (f_{AOM_i}). Although beams of phase modulation light having different frequencies are used to identify a plurality of beams of local oscillation light in Embodiment 3, a plurality of beams of local oscillation light are identified by individually setting a frequency shift amount in Embodiment 4. In other words, although the modulated signal source 10, the optical phase modulator 8, and the mixer 12 are used to identify beams of local oscillation light in Embodiment 3, these components are not used in Embodiment 4. On the other hand, all frequency shift amounts superimposed by the optical frequency shifter 9 are the same frequency shift amounts (f_{AOM}) to coherently synthesize synthesized outputs in a signal light path.

Next, an entire operation will be described. Laser light from the reference light source 1 is split into a plurality of beams to obtain a plurality of beams of local oscillation light. Mutually different frequency shifts are added to the plurality of beams of local oscillation light by an element circuit 31-i (i=1 to N). As illustrated in FIG. 9, a reference signal source 33-i outputs a reference signal of a certain frequency f_{AOM_i}, and the frequency f_{AOM_i} mutually differs in a case of i=1 to N. An optical frequency shifter 35-i is tuned to a corresponding center frequency.

The element circuits 24 (24-1−1 to 24-N−N_{S}) for signal light convert side carrier beat signals generated by heterodyne detection of local oscillation light and signal light subjected to phase modulation into f_{AOM_s}−f_{AOM_i}. After an unnecessary signal is suppressed by the band limiting filter 17 at the center frequency f_{AOM_s}−f_{AOM_i}, the phase of a signal output from the band limiting filter 17 and the phase of the reference signal (f_{AOM_s}−f_{AOM_i}) are compared by the phase comparator 14 to establish phase synchronization.

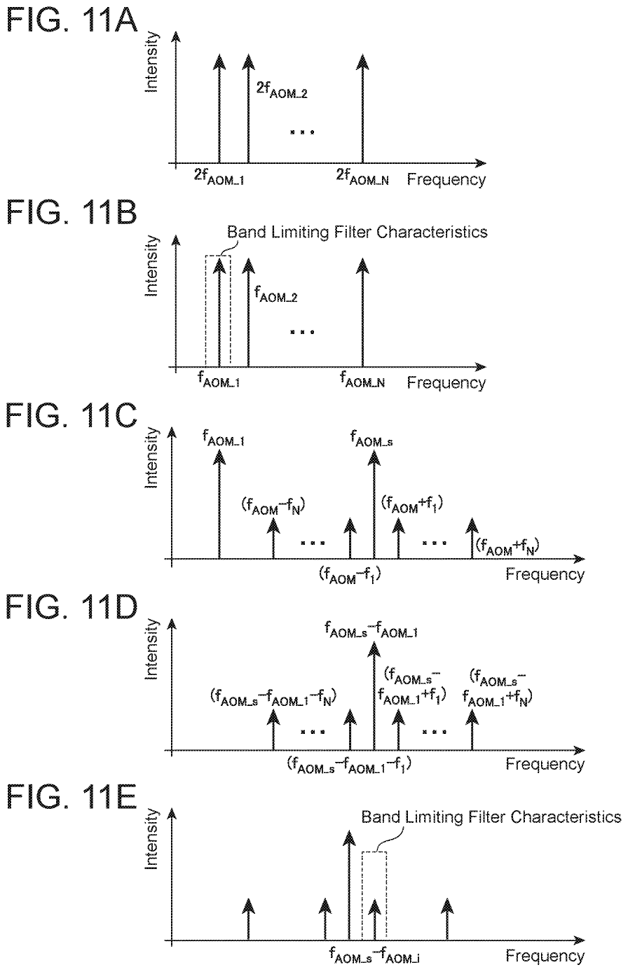

FIG. 11 illustrates the spectra of signals at respective stages. FIG. 11A is a conceptual view of the spectrum of a received signal of a local oscillation light unit. FIG. 11B is a conceptual view of the spectrum of a received signal divided by the ½ frequency divider 11.

FIG. 11C is a conceptual view of the spectrum of a light signal of a subarray #1. FIG. 11D is a conceptual view of the spectrum of the received signal of the subarray #1. FIG. 11E is a conceptual view of the spectrum of a received signal of the subarray #1 band-limited by the band limiting filter 17.

As in Embodiment 4, by individually setting the frequencies of a plurality of beams of local oscillation light, it is possible to eliminate frequency components unnecessary for the beams of local oscillation light. Consequently, it is possible to reduce side carrier signals generated by phase modulation at a time of heterodyne detection of signal light and local oscillation light, and implement phase synchronization with a simple configuration.

### Embodiment 5

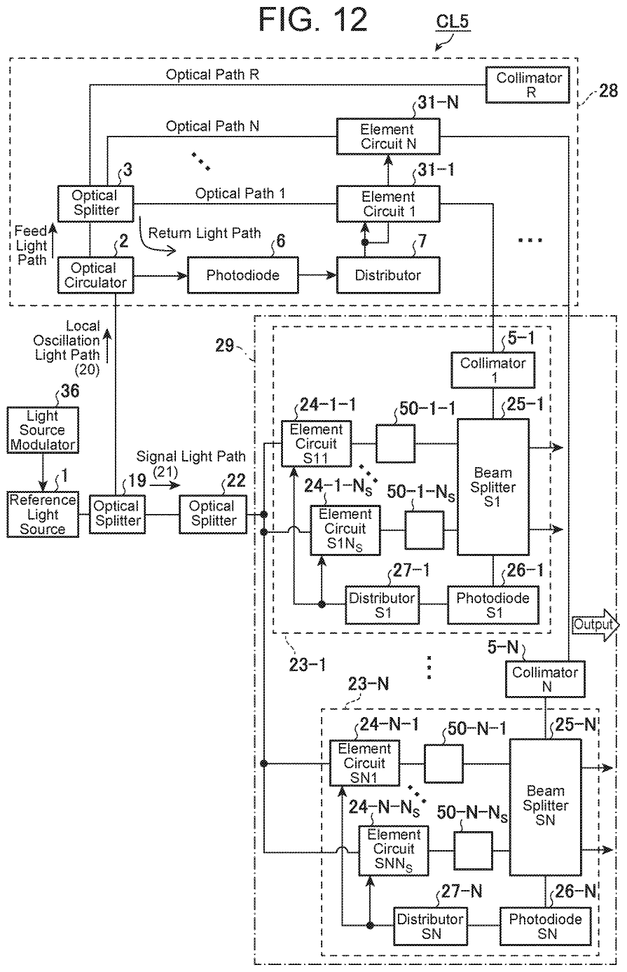

Hereinafter, a phase synchronization laser device CL5 according to Embodiment 5 of the present disclosure will be described with reference FIG. 12. FIG. 12 is a diagram illustrating an entire configuration example of the phase synchronization laser device CL5. The same or similar elements as those of Embodiment 1, Embodiment 2, Embodiment 3, or Embodiment 4 in FIG. 12 will be assigned the same reference numerals, and description thereof will not be repeated.

Embodiment 5 differs from Embodiment 4 in including a light source modulator 36 that modulates the reference light source 1 in Embodiment 5. Although Embodiment 4 has described the phase synchronization laser device including the reference light source 1 that emits laser light having a narrow line width, an output of the high power optical amplifier 30 is restricted due to a non-linear optical effect in this case. By superimposing frequency modulation or phase modulation on the reference light source 1 as in the present embodiment, it is possible to achieve a wider band of the line width of the reference light source 1 in a pseudo manner, so that it is possible to achieve higher power.

Note that the embodiments can be combined, and each embodiment can be modified or omitted as appropriate.

### INDUSTRIAL APPLICABILITY

The phase synchronization laser device according to the present disclosure can be used as, for example, a laser device for laser machining.

### REFERENCE SIGNS LIST

1: Reference light source, 2: Optical circulator, 3: Optical splitter, 4 (4-1 to 4-N): Element circuit, 5 (5-1 to 5-N+1): Collimator, 6: Photodiode, 7: Distributor, 8: Optical phase modulator, 9: Optical frequency shifter, 10: Modulated signal source, 11: ½ frequency divider, 12: Mixer, 13: Reference signal source, 14: Phase comparator, 15: Loop filter, 17: Band limiting filter, 18: Semiconductor optical amplifier, 19: Optical splitter, 20: Local oscillation light path, 21: Signal light path, 22: Optical splitter, 23: Signal light subarray, 24 (24-1−1 to 24-N−N_{S}): Element circuit (second element circuit), 25: Beam splitter, 26: Photodiode, 27: Distributor, 28: Local oscillation light control unit, 29: Signal light control unit, 30: High power optical amplifier, 31 (31-1−1 to 31-N): Element circuit (first element circuit), 33-i: Reference signal source, 35-i: Optical frequency shifter, 36: Light source modulator, CL (CL1 to CL5): Phase synchronization laser device, 50 (50-1 to 50-N−N_{S}): Collimator

1. A phase synchronization laser device comprising:
an optical circulator to accept, from a first port, laser light emitted from a reference light source, supply the laser light to a feed light path, and output, from a second port, return light accepted from a return light path;
an optical splitter to split the laser light accepted from the optical circulator via the feed light path into reference light and a plurality of beams of signal light;
a plurality of element circuits each including a phase compensator to perform phase control on the plurality of beams of signal light split by the optical splitter, and output the plurality of beams of signal light subjected to the phase control;
a plurality of optical partial reflection mirrors to allow the reference light or the plurality of beams of signal light subjected to the phase control to enter as beams of incident light, reflect part of the beams of incident light as beams of reflection light, and allow a rest of the beams of incident light to transmit; and
a photoelectric converter to accept and photoelectrically convert the return light, and output a photoelectrically converted electrical signal, the return light being laser light obtained by the optical splitter by multiplexing the plurality of beams of reflection light, wherein
each element circuit performs frequency conversion on the electrical signal output by the photoelectric converter, and detects a phase error of the electrical signal having a frequency component corresponding to each element circuit, and
each phase compensator compensates for the detected phase error.

2. The phase synchronization laser device according to claim 1, wherein each element circuit includes at a subsequent stage of each phase compensator a semiconductor optical amplifier that does not include an isolator at an input-output end.

3. A phase synchronization laser device comprising:
a signal light control unit including a plurality of signal light subarrays obtained by subarraying a plurality of beams of signal light obtained from laser light emitted from a reference light source; and
a local oscillation light control unit to supply a plurality of beams of local oscillation light subjected to phase synchronization with the plurality of signal light subarrays, wherein
the local oscillation light control unit includes
an optical circulator to accept, from a first port, the laser light, supply the laser light to a feed light path, and output, from a second port, return light accepted from a return light path,
an optical splitter to split the laser light accepted from the optical circulator via the feed light path into reference light and the plurality of beams of local oscillation light,
a plurality of first element circuits each including a phase compensator to perform phase control on the plurality of beams of local oscillation light split by the optical splitter, and output the plurality of beams of local oscillation light subjected to the phase control,
a plurality of optical partial reflection mirrors to allow the reference light or the plurality of beams of local oscillation light subjected to the phase control to enter as beams of incident light, reflect part of the beams of incident light as beams of reflection light, and allow a rest of the beams of incident light to transmit, and
a first photoelectric converter to accept and photoelectrically convert the return light, and output a photoelectrically converted electrical signal, the return light being laser light obtained by the optical splitter by multiplexing the plurality of beams of reflection light,
each first element circuit performs frequency conversion on the electrical signal output by the first photoelectric converter, and detects a phase error of the electrical signal having a frequency component corresponding to each element circuit, and
each phase compensator compensates for the detected phase error.

4. The phase synchronization laser device according to claim 3, wherein each signal light subarray includes
a beam splitter to photomix part of beams of transmission light and the beams of local oscillation light and generate mixed light,
a second photoelectric converter to photoelectrically convert the mixed light and output the photoelectrically converted electrical signal, and
a second element circuit to compensate for a phase error of one of the plurality of beams of signal light using the electrical signal output from the second photoelectric converter.

5. The phase synchronization laser device according to claim 4, wherein the plurality of beams of local oscillation light are identified from each other by phase modulation.

6. The phase synchronization laser device according to claim 4, wherein
the local oscillation light control unit includes an optical frequency shifter to superimpose respectively different frequency shift amounts to identify the plurality of beams of local oscillation light, and
the signal light control unit includes an optical frequency shifter to superimpose identical frequency shift amounts.
